(19) United States
(12) Patent Application Publication
(10) Pub. No.: US 2018/0261288 A1
(43) Pub. Date: Sep. 13, 2018

(54) LOOP MEMORY CELL

(71) Applicant: Ted Greg Lee FRUMKIN, Herzliya (IL)

(72) Inventor: Ted Greg Lee FRUMKIN, Herzliya (IL)

(21) Appl. No.: 15/919,280

(22) Filed: Mar. 13, 2018

Related U.S. Application Data
(60) Provisional application No. 62/470,371, filed on Mar. 13, 2017.

(51) Int. Cl. G11C 13/04; G02B 6/12; G02B 6/293; G02F 1/01; G02B 6/036; G02B 6/122

(52) U.S. Cl. CPC G11C 13/047; G02B 6/12004; G02B 6/2934; G02B 6/1223; G02F 1/0118; G02B 6/03616; G11C 13/044

(57) ABSTRACT

A loop memory cell (LMC) includes a minimum of one optical loop coupled by a minimum of one input armlet and on output armlet. The input armlet(s) can couple only in one direction, from the input armlet(s) into the optical loop, and not back. The output armlet(s) can couple or not, according to the refractive index changer, from the optical loop into the output armlet(s). The LMC is configured to collect the input data and store the date in the optical loop until needed. Changing the refractive index the LMC can act as a memory cell or modulator. The LMC overcomes the energy loss of conventional techniques, allowing the creation of variety of building blocks and complex processing blocks for different applications and algorithms. The LMC has increased information storing efficiency, increased data processing speeds, and can modulate data thereby reducing processing complexity and increasing speeds.

### FIELD OF THE INVENTION

The present invention generally relates to memory cell a fundamental building block of data storage, and in particular, it concerns optical and electro optical memory cell and modulation.

### BACKGROUND OF THE INVENTION

The amount of data produced, processed, and transmitted around the world is growing on a daily basis, increasing the efficiency, data processing rate and information transmission while reducing cost is a desideratum. Notwithstanding the advantages of optical technology has in enhanced data rate capabilities, noise rejection, carrier mobility, large bandwidth etc., despite the clear advantages that optical technology has compared to their electronic counterparts most of the data is still processed mainly in electrical manner. A key reason for the continued use of electrical processing is due to lack of sufficient optical or mixed electro-optical building and processing blocks, that are essential to many different applications and algorithms, in particular fundamental building blocks are missing in the photonic integrated circuit (PIC) sector.

As mentioned earlier in order to create various optical applications and algorithms, which consist out of complex processing blocks, there is therefore a need for improved optical or electro optical building blocks such as a memory cell, allowing forming variety of optical complex processing blocks, with increased data rate capabilities and obtainable energetic efficiency.

### SUMMARY

According to the teachings of the present embodiment there is provided a novel optical or electro optical loop memory cell (will be referred as loop memory cell), that can act also as a modulator, including: a minimum of one optical loop coupled together with minimum of two waveguides armlets. The first waveguide armlet is coupled (connected) in one side to the input and on the other side to the optical loop (will be referred as the input armlet), the data cannot couple back from the loop to the input armlet. Where the secondary waveguide armlet is a refractive index changer waveguide (or a variable coupling control), winch one side of the refractive index changer waveguide armlet is coupled from the optical loop and the other side is coupled to the output (will be refereed as the output armlet).

In an optional embodiment, the output armlet refractive index can change by adding optical energy (illumination of different wavelengths), making it an all-optical loop memory cell. In another optional embodiment, the output armlet refractive index can change by adding electrical energy, making it an electro-optical loop memory cell or modulator. In another optional embodiment, the output armlet refractive index can change by all materials and techniques that change the refractive index on the required demand. In an optional embodiment, the input armlet can be a refractive index changer waveguide.

In another optional embodiment, the input armlet can be coupled into (overlapping or by proximity) by an external waveguide. In another optional embodiment, the output armlet can be coupled out to (overlapping or by proximity) an external waveguide. In another optional embodiment, the output armlet can couple back into the external input waveguide. In another optional embodiment, the output can couple back into the input armlet, and creating unclassified shape loop or a secondary optical loop (multi loop). In another optional embodiment, the optical loop can contain airy shape and size depending on the requirements as long as it consisting with the propagation restrictions.

In another optional embodiment, the optical loop can contain a plurality of input and output armlets, or plurality of input armlets and one output armlet, or one input armlet and a plurality of output armlets. In another optional embodiment, the optical loop can be used for a single mode or multimode.

In another optional embodiment, plurality of loop memory cells can be connected in parallel with the same external input and output waveguides, or the same external input waveguide and plurality of external output waveguides. In another optional embodiment, plurality of loop memory cells can be connected in series, where the output armlet of the first loop memory cell is the input armlet of the secondary memory cell. In another optional embodiment, plurality of loop memory cells can be connected one inside the other, where the input armlet of the external loop memory cell is connected to the input armlet of the inner loop memory cell, the inner loop memory cell output armlet is connected to the inner input armlet.

In another optional embodiment, the armlets and the loop can contain external ring resonators, pumps etc. In another optional embodiment, the loop can be covered by a clad in order to obtain lees propagation loss, as long as the refractive index difference between the loop's waveguide and the clad helps the signal propagate with higher efficiency on the required direction. In another optional embodiment, the loop and can be coupled with other loops and waveguides inside the loop.

In another optional embodiment, logic gats and other algorithms can be applied by a loop memory cell. Applying different combinations of loop memory cell connections creates NOT, AND, OR, NAND, NOR, XNOR gats and algorithms such as Viterbi and convolutional codes.

According to the teachings of the present embodiment there is provided a method for creating an optical or electro optical loop memory cell, the method including the steps of: providing a minimum of one optical loop, coupled together with minimum of one waveguide input armlet and one refractive index changer waveguide output armlet. The input armlet is coupled into the optical loop, where the data is stored until opening the output armlet by changing the refractive index. This concept creates operationally loop memory cell that store and release the data on demand.

According to the teachings of the present embodiment there is provided an apparatus including an optical loop with at least one one-way input coupler, at least one output coupler, and at least one output variable coupling control. The optical loop is coupled to a respective on output coupler via a respective one of the variable coupling control.

In an optional embodiment, one or more of the at least one one-way input coupler is coupled to an input optical signal, and the optical loop receives the input optical signal via the one-way input coupler.

In another optional embodiment, one or more of the respective input optical signals are coupled to respective one-way input coupler via an input variable coupling control.

In another optional embodiment, the input optical signal is carried by an input waveguide.

In another optional embodiment, the one-way input coupler is configured to allow an optical signal to be coupled only into the optical loop.

In another optional embodiment, the variable coupling control can be configured to change a refractive index between the optical loop and the output coupler, so as to configure the variable coupling control as a refractive index changer.

In another optional embodiment, the change is affected by an implementation selected from the group consisting of: Electrical refractive index change; Optical refractive index change; Thermo refractive index change; External materials refractive index change; Graphene refractive index change and Graphene capacitor refractive index change.

In another optional embodiment, the output coupler outputs au optical signal from the optical loop via the output variable control coupling.

In another optional embodiment, the optical loop, the input coupler, and the output coupler construction is selected from the group consisting of: optical fibers; photonic integrated circuit (PIC) waveguides; and free space propagation.

In another optional embodiment, the optical loop repeatedly cycles an electromagnetic signal along a waveguide path.

In another optional embodiment, the output coupler is coupled to an output waveguide.

In another optional embodiment, further including at least one adjacent waveguide, wherein each of the adjacent waveguides is respectively coupled to another adjacent waveguide via a respective output variable coupling control.

In another optional embodiment, each of the adjacent waveguides is coupled to at least one one-way input coupler.

In another optional embodiment, the at least one of the output coupler is coupled to at least one one-way input coupler.

In another optional embodiment, further including a second apparatus connected in parallel to the first apparatus via at least one one-way input coupler.

In another optional embodiment, further including a second apparatus having a second one-way input coupler, wherein one output coupler of the apparatus is connected in series to the second one-way input coupler.

In another optional embodiment, the output variable coupling control is configured on a second optical loop, the second optical loop coupled to the optical loop.

In another optional embodiment, the variable coupling control is controlled by a binary electrical signal.

In another optional embodiment, the variable coupling control is controlled by the binary electrical signal to couple the optical loop to the output coupler, thereby coupling out an optical signal from the optical loop, the optical signal corresponding to storage of a pre-defined data in the optical loop.

### BRIEF DESCRIPTION OF FIGURES

FIG. 1A is an optical ring loop.

FIG. 1B is an optical rectangular loop.

FIG. 1C is an optical unclassified shape loop.

FIG. 1D is an optical multiple loop.

FIG. 2A is an overlapping coupling area.

FIG. 2B is a proximity coupling area.

FIG. 3A is a top view of a ring resonator.

FIG. 3B is a top view of a ring resonator with 2 waveguides.

FIG. 4A is a top view of waveguides with refractive index changer.

FIG. 4B is a cross section of a waveguide with graphene capacitor refractive index changer.

FIG. 5A is a top view of electro optical modulator by coupled waveguides with open refractive index.

FIG. 5B is a top view of electro optical modulator by coupled waveguides with close refractive index.

FIG. 6A is a top view on a loop memory cell basic concept.

FIG. 6B is a top view on a loop memory cell basic concept.

FIG. 6C is a top view on a loop memory cell basic concept.

FIG. 7A is a top view on a loop memory cell basic concept coupled by an external waveguide.

FIG. 7B is a top view on a loop memory cell basic concept coupled in and out with external waveguides.

FIG. 7C is a top view on a loop memory cell basic concept coupled in and out to the same external waveguide.

FIG. 8A is a top view on a loop memory cell basic concept where the output armlet is coupled in to the input armlet.

FIG. 8B is a top view on a loop memory cell basic concept where the output armlet is coupled in to the input armlet.

FIG. 9 is a top view on a loop memory cell with multiple input and output armlets.

FIG. 10A is a top view on a plurality of basic loop memory cells connected in parallel with the same external input waveguide.

FIG. 10B is a top view on a plurality of loop memory cells connected in parallel with the same external input waveguide and one output armlet.

FIG. 11 is a top view on a plurality of basic loop memory cells connected in a series.

FIG. 12 is a top view on a plurality of loop memory cells connected one inside the other.

FIG. 13A is a top view on a basic loop memory cell connected with external accessories.

FIG. 13B is a top view on a loop memory cell with a ring resonator on as the output armlet.

FIG. 13C is a top view on a loop memory cell covered with a clad.

FIG. 14A is a top view on a loop memory cell drawing with two exit armlets.

FIG. 14B is a NOT logic gate created by a loop memory cell.

FIG. 14C is an AND logic gate created by a loop memory cell.

FIG. 14D is an OR logic gate created by a loop memory cell.

FIG. 14E is a NOR logic gate created by a loop memory cell.

FIG. 14F is a NAND logic gate created by a loop memory cell.

FIG. 14G is a XOR logic gate created by a loop memory cell.

FIG. 14H is a XNOR logic gate created by a loop memory cell.

FIG. 14I is a Trellis diagram created by a loop memory cell.

FIG. 14J is a convolutional code created by a loop memory cell.

### DETAILED DESCRIPTION

The principles and operation of the apparatus and method according to a present embodiment may be better understood with reference to the drawings and the accompanying description. A present invention is an apparatus for optical or electro optical (depending on the refractive index changer, all materials and techniques that change the refractive index can be used) loop memory cell that can act as a modulator as well. The apparatus facilitates storing and modulating optical data, using an innovative loop memory cell.

The term “optical loops” referrers to optical data that is locked in a closed loop and has cyclical movement, optical loops in principle can continue storing the data indefinitely, as long as the optical loop stays closed and doesn't have propagation loss (or is pumped in order to compensate for the loss). The loop shape needs to be consistent with the optical energy propagation restrictions (for example, sharp turns and movements that are affected from the wavelength, refractive index etc. and can cause energy loss); one skilled in the art can determine the propagation restrictions. Optical energy can propagate in various ways starting from free space propagation, fibers, waveguides etc. as long as the propagation direction can be controlled an optical loop can be made. Propagating in the waveguide is generally of electromagnetic radiation, typically in the optical wavelengths, referred to as optical signals, “light” such as infra-red (IR, for communication 1400-1600 nm) wavelengths in silicon waveguides. The loop size and shape can be determined according to the requirements, by someone skilled in the art. In figures, arrows represent propagation direction.

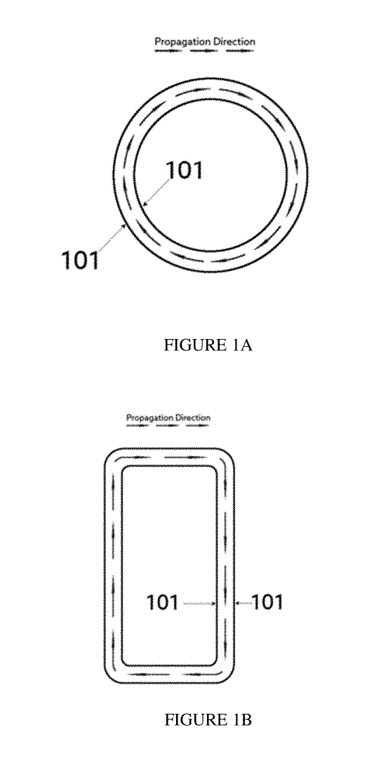

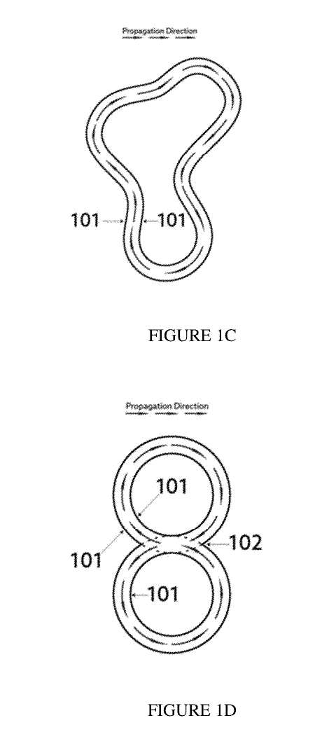

Referring to FIG. 1A, non-limiting example of an optical ring loop, a view from top on a closed ring loop, where arrows point the direction of the propagation. The controlled propagation direction creates the ring shape, where 101 is the boundary of propagation.

Referring to FIG. 1B, non-limiting example of an optical rectangular loop, a view form top on a closed rectangular loop, where the corners of the rectangular bend according to the propagation restrictions, direction of propagation is pointed by arrows. The controlled propagation direction creates the rectangular shape, where 101 is the boundary of propagation.

Referring to FIG. 1C, non-limiting example of an optical unclassified shape loop, a view from top on a closed unclassified shape loop, where the shape is bending according to the propagation restrictions, this is an example that optical loops can contain any shape as long as they consist with the propagation restrictions, the direction of propagation is printed by arrows. The controlled propagation direction creates the unclassified shape, where 101 is the boundary of propagation.

Referring to FIG. 1D, non-limiting example of an optical multiple loop, a view from top on a closed multiple (infinity shape) loop, closed optical loops can be combined together according to the propagation restrictions to create multiple loop direction of propagation is pointed by arrows. The controlled propagation direction creates the infinity shape, where 101 is the boundary of propagation. For clarity, a dashed line draws the propagation inner boundary 102 to show the propagation where the waveguides are overlapping.

The term “waveguide coupling” referring to two or more waveguides that exchange energy between themselves. Coupling between waveguides can occur when the waveguides are overlapping (touching each other at least in one location) or by proximity transmission effect that occurs when the waveguides are close enough, this phenomenon is due to the wave property of light. One skilled in the art can determine the portion of energy coupled between the waveguides.

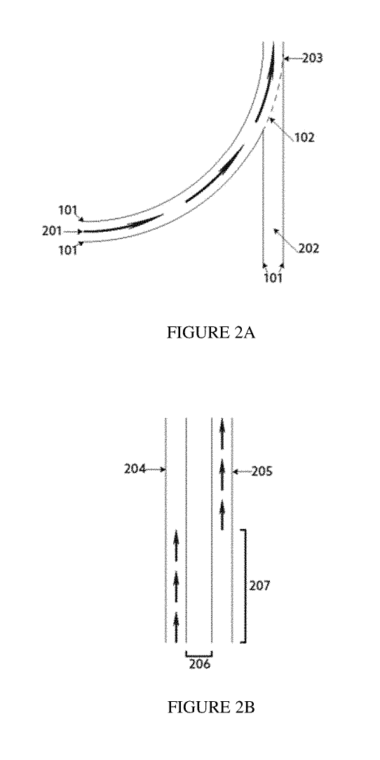

Referring to FIG. 2A, non-limiting example of overlapping coupling area, view from top on waveguide 201 that carries a signal (the direction of propagation is pointed by arrows) and coupled by overlapping with waveguide 202 that do not an a signal (in case both waveguides carry a signal, one skilled in the art can calculate the combined signal outcome). 101 shows the waveguides (propagation) boundary, the boundaries can be in different sizes as long as their overlapping and coupled according to the propagation restrictions. The dashed line 102 show the propagation inner boundary where waveguides 201 and 202 are overlapping to a combined 203 waveguide.

Referring to FIG. 2B, non-limiting example of proximity coupling area, view from top on waveguide 204 that carries a signal (the direction of propagation is pointed by arrows) and coupled by proximity with waveguide 205 that do not carry a signal (both waveguides can carry a signal). Evanescent waves and other properties of the optical wave signal can make proximate waveguides couple, three aspects affect the optical coupling: the distance between the waveguides 206, the coupling length 207 meaning the length that takes the mode (signal) to couple between the proximate waveguides and the refractive indexes of the waveguides and the surroundings. One skilled in the art can find, according to the waveguides and the surroundings refractive indexes, the required distances to couple the signal completely or just a selected fraction from one waveguide to the next. The current figures shows complete coupling.

Optical ring resonator refers to resonators or interferometers that contain an external waveguide coupled with at least one closed loop configuration, in guided waves a ring resonator may be obtained by fabricating a loop channel waveguide with a circular path. The coupling allows the possibility of energy exchange between the waveguides and the ring resonator at the coupling location. We consider an input beam propagating in the waveguide and coupled into the ring, as the beam that circulates inside the ring and completes a full round, the propagating signal in the ring is coupled back into the waveguide, multiple couplings can occur at the couplers.

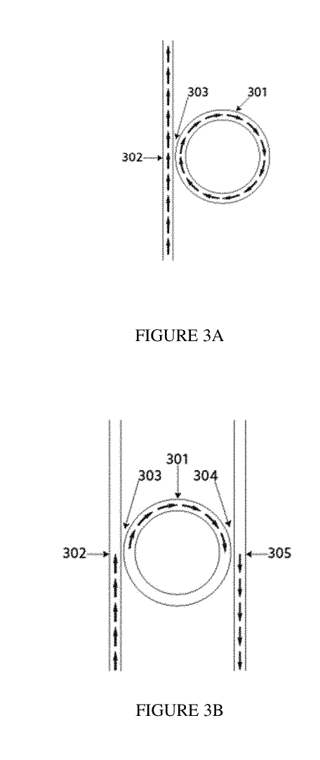

Referring to FIG. 3A, non-limiting example of ring resonator, view from top on waveguide 302 that carries a signal (the direction of propagation is pointed by arrows) and coupled by proximity 303 with a ring loop 301. After the coupled signal inside the ring 301 completes a full round the coupled signals coupled back again into the original waveguide 302. One skilled in the art can find, according to the waveguides (including the closed loop waveguide, the ring) and the surroundings refractive indexes, the required distances to couple the signal completely or just a selected fraction from the waveguide to the ring.

Referring to FIG. 3B, non-limiting example of ring resonator with 2 waveguides, view from top on waveguide 302, that carries a signal (the direction of propagation is pointed by arrows) and fully coupled by proximity 303 into a ring loop 301 which is fully coupled by proximity 304 to waveguide 305 (the waveguide was not carrying any signal before). One skilled in the art can find, according to the waveguides (including the closed loop waveguide, the ring) and the surroundings refractive indexes, the required distances to couple the signal completely or just a selected fraction from the waveguides to the ring and back.

Refractive index changer (the same as the term “variable coupling control”, a more general term including different coupling controllers) refers to waveguides that can change their refractive index on demand. Changing the refractive index (according to the property of light and the propagation restrictions) can be the difference between a signal propagating in the waveguide or not. Several materials and techniques can change the refractive index. For example, by thermodynamics, Chalcogenides glass that can change the refractive index by illumination of different wavelengths. Additional example, silicon excitation with applied voltage, can change the refractive index by order of 10⁻⁴. Another example is adding external materials such as graphene, a single sheet of carbon atoms in a hexagonal lattice, which has exceptional electrical and optical properties. Pure graphene monolayer has a constant absorption that can change the refractive index by order of one, where a graphene capacitor can approximately change the refractive index by order of 3-4. Note: all materials and techniques that change the refractive index can be used.

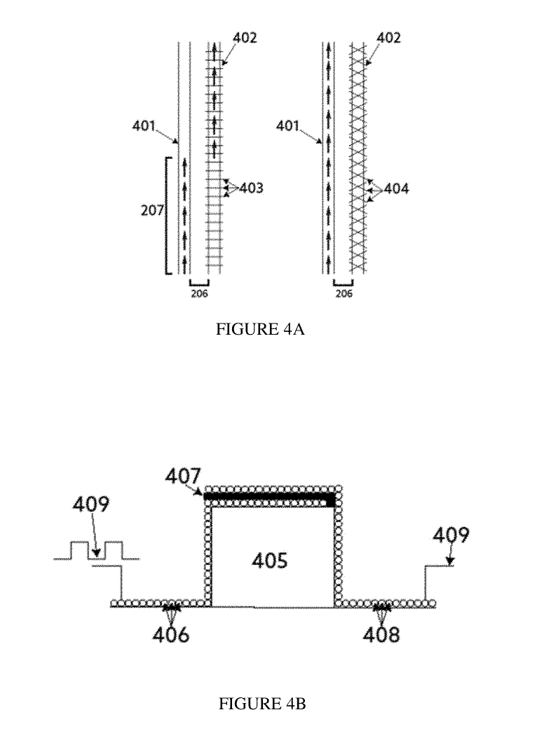

Referring to FIG. 4A, non-limiting example of a waveguide with refractive index changer. View from top on waveguide 401 that carries a signal (the direction of propagation is pointed by arrows) and coupled by proximity with waveguide 402 that does not carry a signal and has open refractive index change 403 that allows propagation in the waveguide, or closed refractive index change 404 that does not allow propagation in the waveguide. 403 and 404 are the same device, a variable coupling control, but for clarity the device is referred to by two terms, depending on the device's operations state: “open refractive index changer 403” allows propagation and coupling in the waveguide, and “closed refractive index changer 404” that prohibits propagation and prevents coupling in the waveguide. The “open” and “closed” states of the variable coupling control are boundary conditions, minimum and maximum operation, to allow 100% or zero percent coupling. However, the coupling control can also be varied to be a partial coupling, allowing a partial amount of the light to couple between waveguides. Three aspects affect the optical coupling, the distance between the waveguides 206, the coupling length 207 and the refractive indexes of the surroundings and the changeable refractive index of the waveguides. One skilled in the art can find according to the waveguides change in refractive indexes, the required distances needed between the waveguides to couple the signal (completely or just a selected fraction), and the voltage that is needed for the refractive index changer.

Referring to FIG. 4B, non-limiting example of a waveguide with graphene capacitor refractive index changer. Cross section of waveguide 405 covered with a graphene capacitor. The graphene capacitor consist out of the first graphene capacitor plate 406, insulating layer 407 (insulating between the two graphene capacitor plates) and the second graphene capacitor plate 408. The graphene capacitor is connected to a voltage supply 409. Changing the voltage will change the refractive index of the waveguide, hence changing the propagation properties, which one skilled in the art can determine.

Electro optical modulators refers to modeling (changing/copying) between electrical signals and optical signals. Telecommunication modulation is a process of varying one or more properties of the signal carriers. Electro-optic graphene modulators have generated exceptional interest due to their high modulation speed, carrier mobility, broadband absorption, and large optical bandwidth that makes an extremely fast broadband electro-optic device possible. Modeling between electrical signals and optical signals, is one of the building blocks for processing data.

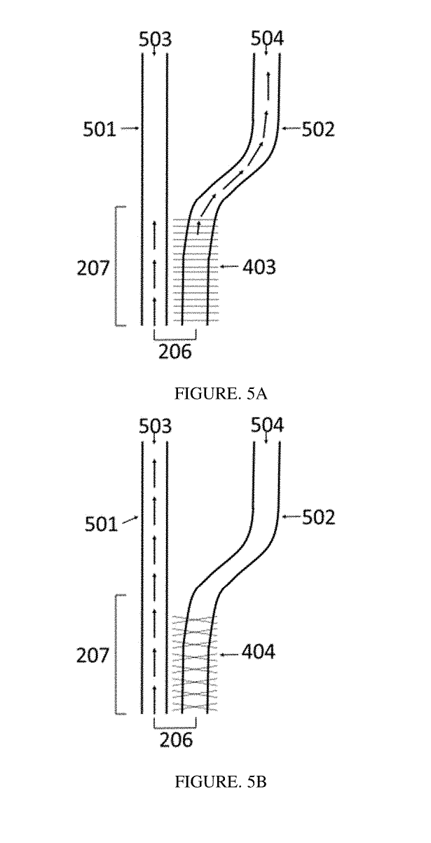

Referring to FIGS. 5A and 5B, non-limiting examples of electro optical modulators by coupled waveguides with refractive index changer. When the voltage changes, so does the optical output. Referring to FIG. 5A, non-limiting example of a view from top on waveguide 501 that carries a signal (the direction of propagation is pointed by arrows) and coupled by proximity with waveguide 502 that does not carry a signal and has open (determine on the voltage supply) refractive index changer 403 that allows propagation in the waveguide. In this example, the output 503 of waveguide 501 is zero and the output 504 of waveguide 502 has a signal (complete coupling). Referring to FIG. 5B, non-limiting example of a view from top on waveguide 501 that carries a signal (the direction of propagation is pointed by arrows) and not coupled by proximity with waveguide 502 that do not carry a signal, due to the closed (determine on the voltage supply) refractive index changer 404 that don't allows propagation in the waveguide. At this example, the output 504 of waveguide 502 is zero and the output 503 of waveguide 501 has a signal. Four aspects affect the optical coupling: the distance between the waveguides 206, the coupling length 207 and the refractive indexes of the surroundings and the changeable refractive index of the waveguides. One skilled in the art can find according to the waveguides change in refractive indexes, the required distances needed for the waveguides to couple the signal (completely or just a selected fraction), and the voltage that is needed for the refractive index changer.

The loop memory cell store optical data inside the loop, the data is coupled in by an input armlet into the loop and cannot couple back again into the input armlet, while the refractive index changer output armlet is closed (meaning the light cannot couple into it, due to the change in the refractive index), the data will stay stored in the loop, opening the output armlet (by changing the refractive index) allows the data stored in the loop to exit, creating the loop memory cell and modulator. The loop memory cell overcomes the energy loss of conventional techniques, allowing longer time for the memory (signal) to be stored in the loop. The loop memory cell can be adjusted to a variety of optical devices including, but not limited to waveguides (photonic integrated circuit, mixed electronic photonic integrated circuit), fibers or by any other way propagating an optical energy signal, while keeping the basic concept of the loop memory cell. The loop memory cell can be adjusted to any product or algorithm that needs to store or modulate data with increased obtainable energetic efficiency, which increase the storing time. The loop memory cell parameters can be adjusted for the required needs, meaning storage time, modulation time, size of the product etc. one skilled in the art can calculate these parameters according to the propagation restrictions.

This loop memory cell enables use in a variety of applications, and is particularly applicable for building blocks such as a memory cell and as a modulator that can be used in large variety of different complex processing blocks, applications, and algorithms. In order to create high efficiency products, devices, and applications with an integrated circuit (chip) there is a need for fast and efficient building blocks such as the loop memory cell.

Current research in the field is focused on improving the conventional use of electrical and optical memory cells. Efforts that are being made include improving electrical and magnetic dynamic and static random-access memory (DRAM and SRAM) which have low speeds compared to the optical properties. Efforts that are being made include improving optical memory cell focuses on optical switches that have low capacities due to the optical switches properties. Efforts are also made in ring resonators that have low storage time due to the multiple couplings that occur at the ring resonator couplers, as the beam circulates inside the ring and completes a full round, the propagating signal in the ring is coupled back into the waveguide. In contrast to conventional research, the current invention includes the use of an optical loop with an input armlet (that cannot be coupled from the loop back) and a refractive index changer output armlet to provide optical or electro optical (depending on the refractive index changer) memory cell with high capacities and storage time.

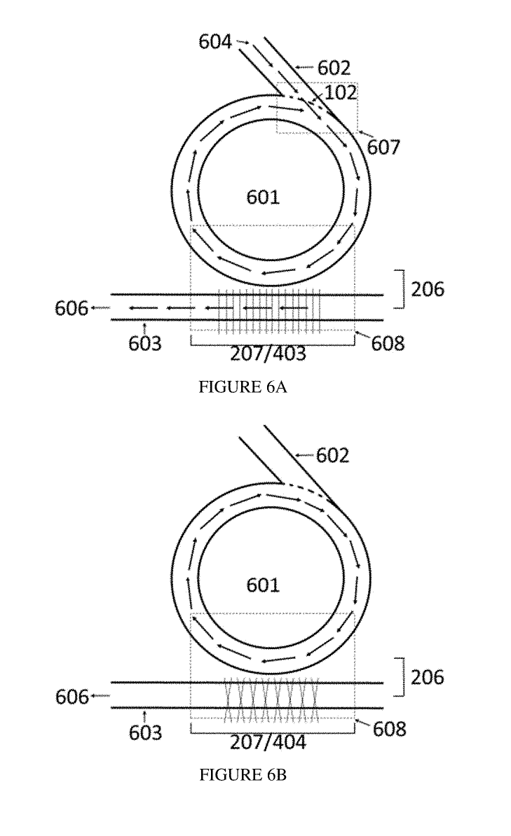

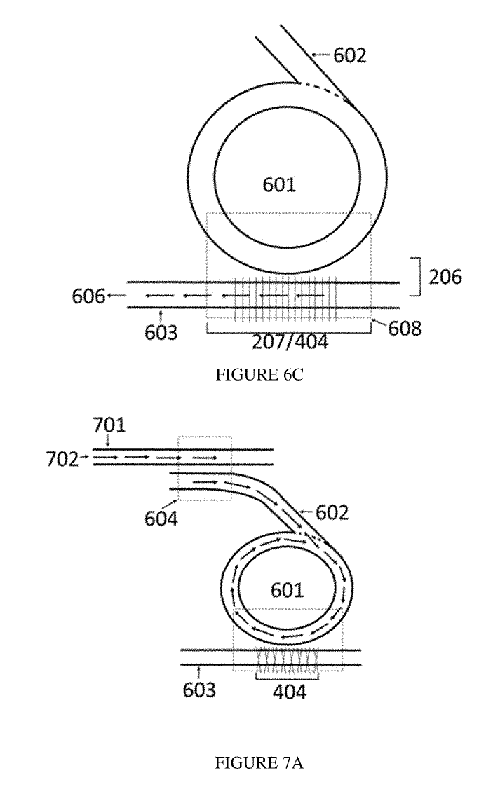

Referring to FIG. 6A, non-limiting example of a top view on a loop memory cell basic concept, this non-limiting example shows an input armlet optical waveguide 602. In the context of this document, the term “optical waveguide” generally refers to a variety of optical devices, including but not limited to optical fibers, photonic integrated circuits (PIC) waveguides, free space propagation, etc. as long as the propagation direction can be controlled. The input armlet waveguide 602 width will be determined according to the needs and the propagation and coupling restrictions, which one skilled in the art can calculate. Note that the current example is for clarity, as the invention is not limited to waveguides, and can be implemented on other optical devices that can transfer optical energy. The input armlet waveguide 602 will simply be referred as input armlet, propagates the optical data from the input 604 to the optical loop 601. In the context of this document, the term “optical loop” generally refers to a variety of optical loops, including but not limited to ring loop, multiple loop, unclassified shape etc. optical loops can contain any shape as long as they consist with the propagation restrictions and the optical data is locked in a closed loop with cyclical movement. Note that the current example is for clarity, as the invention is not limited to ring optical loops, and can be implemented by other optical loops that have cyclical movement. The input armlet 602 is coupled at coupling area 607 at any location on (according to the propagation direction) the optical loop 601. Coupling area is a general term referring to a variety of couplers, including but not limited to overlapping coupling, proximity coupling etc. in the current implementation, the optical data can be coupled from the input armlet to the optical loop, and cannot be coupled again from the optical loop to the input armlet. Note that the current example is for clarity, as the invention is not limited to overlapping coupling from the input armlet to the optical loop, and can be implemented by other optical couplers as long as the optical energy can couple only in one direction, from the input armlet to the optical loop.

Any location on (according to the propagation direction) the optical loop 601 can be coupled at the coupling area 608 to the output armlet 603. Coupling area as a general term referring to a variety of couplers, including but not limited to overlapping coupling, proximity coupling etc. as long as the optical data can be coupled (couple the signal completely or just a selected fraction) from the optical loop to the output armlet. Note that the current example is for clarity, as the invention is not limited to proximity coupling from the optical loop to the output armlet, and can be implemented by other optical couplers. The output armlet optical waveguide 603 has refractive index changer properties. In the context of this document, the term “refractive index changer” generally refers to a variety of ways to change the waveguide refractive index, including but not limited to external energetic change, such as voltage change, illumination of light, heat change, and to different external material such as graphene monolayer, graphene capacitor etc. Note that the current example is for clarity, as the invention is not limited to a specific refractive index changer, and can be implemented by any variable coupling controls or techniques to change the refractive index of the waveguide, as long as the refractive index changes on specific demands and can be measurable. The output armlet 603 propagates the optical data that is coupled from the optical loop 601 to the output 606. Preferably, the materials, shape, distances, refractive indexes, coupling techniques etc. for the input and output armlets and the optical loop, can be determined according to the propagation and coupling restrictions by one that is skilled in the art.

In the current non-limiting example, the direction of propagation (that is pointed by arrows) of a constant flow signal in an open loop memory cell. The input 604 is directed by the input armlet 602 to the coupling area 607 with the optical loop (ring) 601, where 102 a dashed line that show the overlapping between the input armlet 602 and the optical loop 601. The optical loop 601 is partially proximity coupled at the coupling area 608 to the output armlet 603, the part of the signal that is not coupled continues to propagate in the optical loop 601. The output armlet 603 has an open refractive index changer 403 with a length that is equal or greater than the coupling length 207 (in order to prevent coupling when needed), the coupling length is depended on the refractive indexes and the coupling distance 206 between the optical loop 601 and the output armlet 603. The output armlet 603 is directing the coupled signal from the optical loop 601 to the output 606.

Referring to FIG. 6B, non-limiting example of a top view on a loop memory cell basic concept, this non-limiting example shows the direction of propagation (that is pointed by arrows) of a bit (a basic signal/unit of information) in a closed loop memory cell. After the bit (signal) is coupled from the input armlet 602 (which cannot be coupled back again) in to the optical loop 601, the bit will stay stored in the optical loop 601. As long as the output armlet 603 has a closed refractive index changer 404 with a length that is equal or greater than the coupling length 207 (in order to prevent coupling), the coupling length is depended on the refractive indexes and the coupling distance 206 between the optical loop 601 and the output armlet 603. The bit will stay stored inside the optical loop 601 and will not feel the coupling area 608 due to the closed refractive index changer 404.

Referring to FIG. 6C, non-limiting example of a top view on a loop memory cell basic concept, this non-limiting example shows the direction of propagation (that is pointed by arrows) of a bit (signal) in an open loop memory cell. The bit propagates in the opened refractive index 403 output armlet 603 to the output 606 direction. In order for the bit to propagate in the output armlet 603, first, the bit must propagate from the input armlet 602 and couple in to the optical loop 601 until the refractive index changer 403 will open. With the open refractive index changer 403 the optical loop 601 is fully (the entire signal is coupled) proximity coupled at the coupling area 608 to the output armlet 603. Where the distance 206 and coupling length 207 between the optical loop 601 and the output armlet 603, be determined by one skilled in the art according to the refractive indexes, in order for the signal to fully couple.

In accordance with FIG. 6B and FIG. 6C, non-limiting examples of a top view on a loop memory cell, one may better understand the process of the memory cell and the modulator basic concept. After the signal is coupled from the input armlet 602 in to the optical loop 601, as long is the refractive index stays closed 404, the propagating bit will be locked (stored) in the optical loop 601, meaning the output 606 will not have a signal. When the refractive index is open 403, the propagating bit will couple into the output armlet 603, meaning the output 606 will have a signal. Hence, a memory cell can be issued as long as the refractive index changer can be controlled on demand. In the case where the refractive index changer between open 403 and close 404 occurs by changing the electrical energy (or any other energy change), the basic concept of the loop memory cell can act as a modulator. Meaning the output 606 optical signal will depend on the electrical signal that change the refractive index. Hence making the loop memory cell, act as an electro-optical modulator.

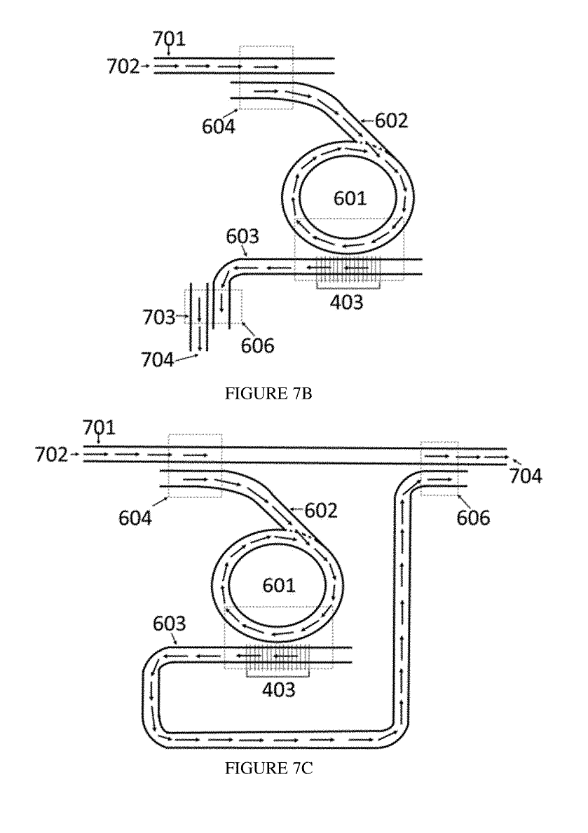

Referring to FIG. 7A, non-limiting example of a top view on a loop memory cell basic concept coupled by an external waveguide, this non-limiting example shows the direction of propagation (that is pointed by arrows) of a constant flow signal in a closed loop memory cell. Note the constant flow is for better understanding the propagation direction in all the system, constant flow or a bit signal can be used according to the application needs. The input 702 is directed by the input external waveguide 701 to the coupling area 604 where is fully (for better understanding the propagation direction and en be as well partially coupled) proximity coupled (all couplers are possible to use) at the coupling area 604 with the input armlet 602. After the signal propagates from the input armlet 602 in to the optical loop 601, the data is stored in the optical loop 601 due to the closed refractive index changer 404 at the output armlet 603.

Referring to FIG. 7B, non-limiting example of a top view on a loop memory cell basic concept coupled in by an input external waveguide and coupled out to an output external waveguide, this non-limiting example shows the direction of propagation (that is pointed by arrows) of a constant flow signal in a opened loop memory cell. The input 702 is directed by the input external waveguide 701 to the coupling area 604 where is fully proximity coupled at the coupling area 604 with the input armlet 602. The input armlet 602 is directing and coupling the data to the optical loop 601. The optical loop 601 is partially coupled (for better understanding the propagation direction in all the system, can be fully coupled) when the refractive index changer is open 403, to output armlet 603. The output armlet 603 has an open refractive index changer 403 enabling to extract the data stored in the optical loop 601. The output armlet 603 is directing the propagation of the data to the coupling area 606 where is fully proximity coupled (all couplers are possible) to an external output waveguide 703 and to the output 704.

Referring to FIG. 7C, non-limiting example of a top view on a loop memory cell basic concept coupled in and out with an external waveguide, this non-limiting example shows the direction of propagation (that is pointed by arrows) of a constant flow signal in a opened loop memory cell. The input 702 is directed by the external waveguide 701 to the coupling area 604 where is fully proximity coupled at the coupling area 604 with the input armlet 602. The input armlet 602 is directing and coupling the data to the optical loop 601. The optical loop 601 is partially coupled (for better understanding the propagation direction in all the system) when the refractive index changer is open 403, to output armlet 603. The output armlet 603 has an open refractive index changer 403 enabling to extract the data stored in the optical loop 601. The output armlet 603 is directing the propagation of the data to the coupling area 606 where is fully proximity coupled (all couplers are possible) to the external waveguide 701 and to the output 704. Note the coupling area 606 can be located, according to the propagation direction, in front or after the coupling area 604 depending on the application needs.

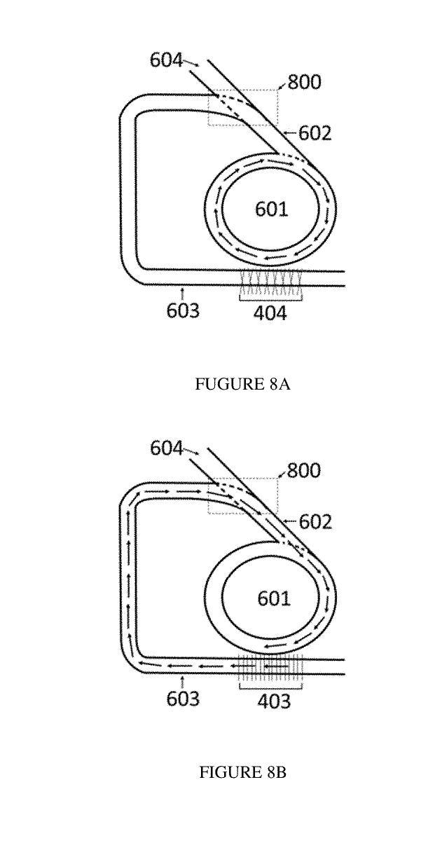

Referring to FIG. 8A, non-limiting example of a top view on a loop memory cell basic concept where the output armlet is coupled in to the input armlet, this non-limiting example shows the direction of propagation (that is pointed by arrows) of a bit signal in a closed loop memory cell. After the input bit (signal) propagation passes the overlapping (all couplers are possible) coupling area 800 between the input armlet 602 and the output armlet 603, the bit will couple from the input armlet 602 (which cannot be coupled back again) in to the optical loop 601. Where the bit will stay stored in the optical loop 601 as long as the output armlet 603 has a closed refractive index changer 404.

Referring to FIG. 8B, non-limiting example of a top view on a loop memory cell basic concept where the output armlet is coupled in to the input armlet, this non-limiting example shows the direction of propagation (that is pointed by arrows) of a bit signal in an opened loop memory cell. After the input bit (signal) propagation passes the overlapping (all couplers are possible) coupling area 800 between the input armlet 602 and the output armlet 603, the bit will couple from the input armlet 602 in to the optical loop 601 until the refractive index changer 403 will open. With the open refractive index changer 403 the optical loop 601 is fully proximity coupled to the output armlet 603. When the optical loop 601 is fully coupled in to the output armlet 603 it creates an unclassified optical loop. The unclassified optical loop shape contains the input armlet 602, a part of the optical loop 601 and the output armlet 603. When the optical loop 601 is partially coupled in to the output armlet 603 it creates a multiple optical loop. The multiple optical loop shape contains the loop of the input armlet 602 combined with the output armlet 603 and the optical loop 601.

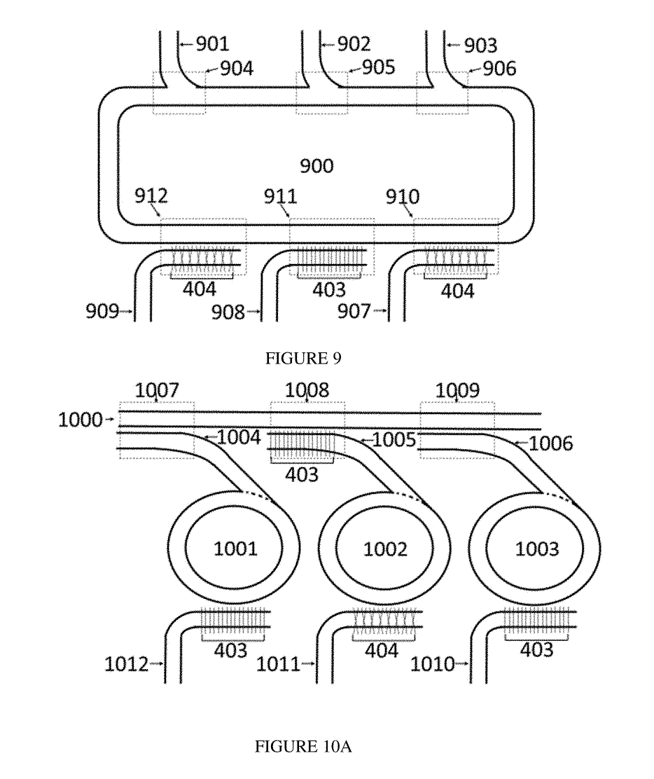

Referring to FIG. 9, non-limiting example of a top view on a loop memory cell with multiple input and output armlets, this non-limiting example shows a loop memory cell with three input armlets and three output armlets. Input armlets 901, 902, 903 are coupled to the optical loop 900 in the coupling area 904, 905, 906 respectively (all couplers are possible to use as long as the coupling occurs only on one direction, from the input armlet to the optical loop). The optical loop 900 will couple, depending if the refractive index changer is open 403 or closed 404, to the output armlets 907, 908, 909 at the coupling area 910, 911, 912 respectively (all couplers are possible to use as long as when the refractive index is closed, the signal cannot couple). Note, the amount of input armlets and output armlets are depended on the application and the required needs, there can be different configurations for example, one input armlet with multiple output armlets or multiple input armlets and one output armlet etc. The signal can be partially (this way can couple to more than one output armlet) or fully coupled out from the optical loop 900 to the output armlet or armlets, depending on the required needs. Note, the multiple armlets memory cell can contain a multimode or multi wavelengths, where the input and output armlets can be adjusted for specific modes or wavelengths.

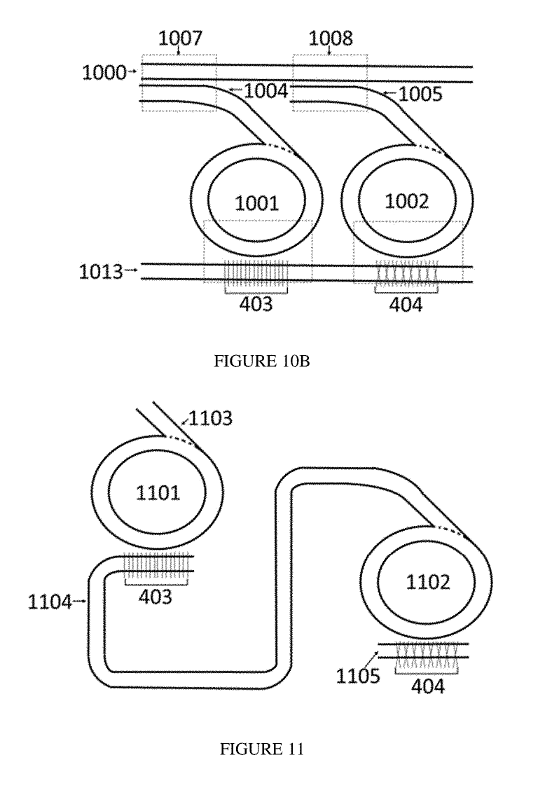

Referring to FIG. 10A, non-limiting example of a top view on a plurality of basic loop memory cells connected in parallel with the same external input waveguide, this non-limiting example shows three loop memory cells connected in parallel by an external waveguide. The input external waveguide 1000 is coupled in to the input armlets 1004, 1005, 1006 at the coupling area 1007, 1008, 1009 respectively (all couplers are possible to use and can be fully or partially coupled). The input armlets 1004, 1005, 1006 are coupled in to the optical loops 1001, 1002, 1003 respectively. The optical loops 1001, 1002, 1003 will couple, depending if the refractive index changer is open 403 or closed 404, to the output armlets 1012, 1011, 1010 respectively. Note, the amount of parallel loop memory cells are depended on the application and the required needs. Each loop memory cell can have different configurations for example, the shape of the loop, multiple armlets loop memory cell etc. The input armlets can have refractive index changer as well, as shown in the coupling area 1008 between the input external waveguide 1000 and the input armlet 1005 with an open refractive index 403.

Referring to FIG. 10B, non-limiting example of a top view on a plurality of loop memory cells connected in parallel with the same external input waveguide and one output armlet, this non-limiting example shows two loop memory cells with one output armlet connected parallel by an external waveguide. The input external waveguide 1000 is coupled in to the input armlets 1004, 1005 at the coupling area 1007, 1008 respectively (all couplers are possible to use and can be fully or partially coupled). The input armlets 1004, 1005 are coupled to the optical loops 1001, 1002 respectively. The optical loops 1001, 1002 will couple, depending if the refractive index changer is open 403 or closed 404, to a connected output armlet 1013. Note, the configurations and amount of parallel loop memory cells are depended on the application and the required needs.

Referring to FIG. 11, non-limiting example of a top view on a plurality of basic loop memory cells connected in a series, this non-limiting example shows two loop memory cells connected in a series where the output armlet of the first loop memory cell is the input armlet of the next memory cell. The input armlet 1103 is coupled in to the optical loop 1101, which is coupled to the output armlet 1104 with open refractive index changer 403. The output armlet 1104 of optical loop 1101 is the input armlet of optical loop 1102. The data coupled from the output/input armlet 1104 into the optical loop 1102 is stored, due to the close refractive index 404 on the output armlet 1105 of the optical loop 1102. Note the amount of loop memory cells connected in a series depends on the application and the required needs. Each loop memory cell can have different configurations for example, the shape of the loop, multiple armlets loop memory cell etc. The output armlet can be split to two (or more), where one part is continuing the series and the other part to an output.

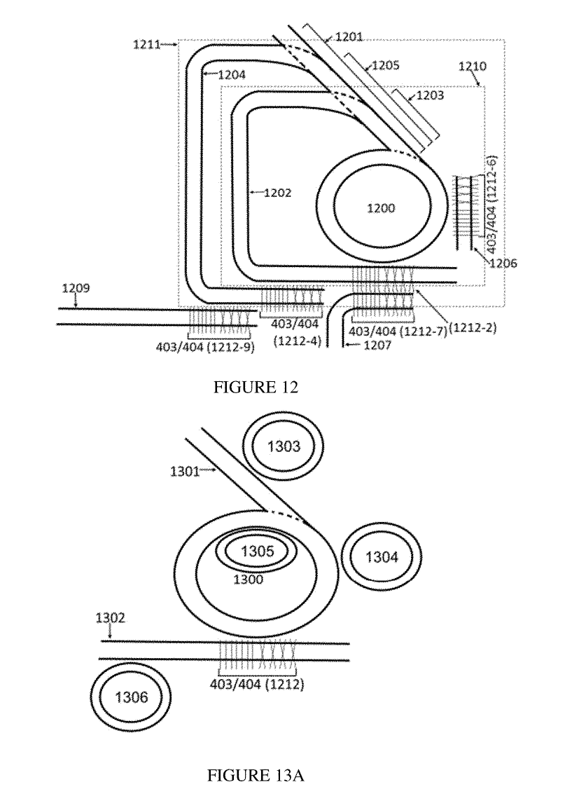

Referring to FIG. 12, non-limiting example of a top view on a plurality of loop memory cells connected one inside the other, a loop memory cell within a loop memory cell. This non-limiting example shows three loop memory cells connected one inside the other, where the input armlet of the external loop memory cell is connected to the input armlet of the inner loops memory cell, where the inner loops memory cell output armlet is connected to the inner input armlet. The input armlet 1201 is coupled into the optical loop 1200, were the data can be stored or not in the optical loop 1200 depending if the output armlet 1202 refractive index changer is closed 404 or open 403 (that can be replaced with variable coupling controls 1212-2). If the output armlet 1202 refractive index is open 403 (1212-2 directs the signal [couples the optical signal from optical loop 1200] to waveguide 1202) the second optical (unclassified) loop 1210 is created, the optical loop 1210 length contains the input armlet 1203, optical loop 1200, and the output armlet 1202. The data can be stored or not in the optical loop 1210 depending if the output armlet 1204 refractive index changer is closed 404 or open 403 (that can be replaced with variable coupling controls 1212-4). If the output armlet 1204 refractive index is open 403 (1212-4 directs the signal to waveguide 1204) the third optical (unclassified) loop 1211 is created, the optical loop 1211 length contains the input armlet 1205, optical loop 1200, and the output armlet 1204. The data can be stored or not in the optical loop 1211 depending if the output armlet 1209 refractive index changer is closed 404 or open 403 (that can be replaced with variable coupling controls 1212-9), creating a loop memory cell within a loop memory cell. The inner optical loops 1200, 1210 can contain an extra output armlet 1206, 1207 (where 1212-6 directs the signal to waveguide 1206 and 1212-7 directs the signal to waveguide 1207) respectively to extract the data. Note, the configurations and amount of loop memory cells within the loop memory cells are depended on the application and the required needs. The data can be fully coupled of partially coupled (depending on the required needs) from the optical loops to the output armlets creating an optical multiple loop.

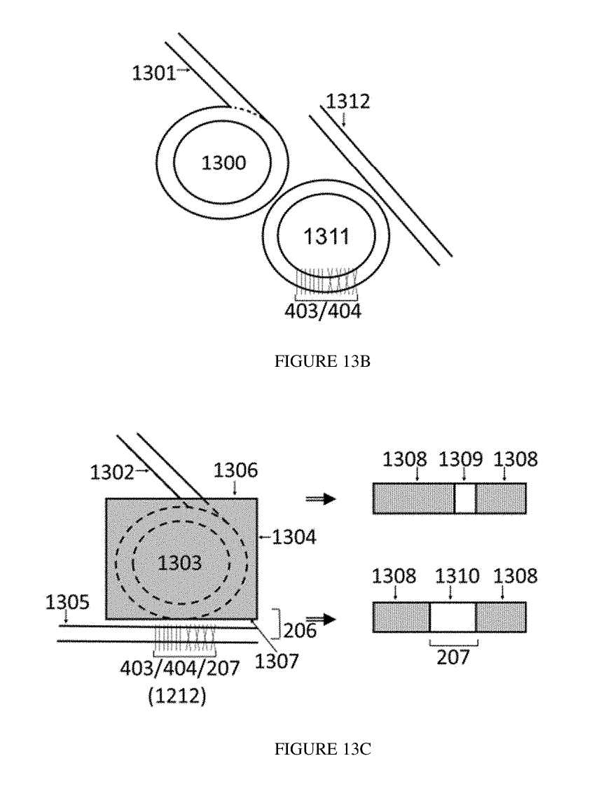

Referring to FIG. 13A, non-limiting example of a top view on a basic loop memory cell connected with external accessories, this non-limiting example shows a loop memory cell that can be connected to external accessories (in this case a ring resonator, but can be any other devices such as a pump etc.) in different locations. The loop memory cell contains the basic input armlet 1301 that is coupled to the optical loop 1300, the optical loop will couple to the output armlet 1302 depending if the refractive index changer is open 403 or closed 404 (that can be replaced with variable coupling controls 1212). The external accessories (in this case ring resonator) can be added in different location. For example, a ring resonator 1303 can be added on the input armlet 1301, a ring resonator 1304 can be added on the external boundaries of the optical loop 1300, a ring resonator 1305 can be added on the inner boundaries of the optical loop 1300 or a ring resonator 1306 can be added on the output armlet 1302. Note all accessories can be added according to the required needs as long as they not conflict with propagation and optical properties restrictions.

Referring to FIG. 13B, non-limiting example of a top view on a loop memory cell with a ring resonator as the output armlet. This non-limiting example shows a loop memory cell that can contain an output armlet where the refractive index changer is located in a different location that acts as a variable coupling control. When the refractive index changer, the ring resonator can be critically coupled in resonance with the loop memory cell in order to extract the information, where the refractive index changer is located far from the loop memory cell. The loop memory cell contains the basic input armlet 1301 that is coupled to the optical loop 1300, the optical loop will couple to the ring resonator 1311 if the refractive index changer is open 403 and will not couple if the refractive index changer is closed 404 (the optical loop will critically couple to the ring resonator on resonance, that changes according to the refractive index). From the ring resonator the information will be coupled directly to the exit waveguide 1312. Note: there can be more than one exit waveguide and can be located anywhere on the ring resonator.

Referring to FIG. 13C, non-limiting example of a loop memory cell covered with a clad, this non-limiting example shows a loop memory cell that is covered with a clad in order to minimize the propagation loss when the data is stored at the optical loop. This non-limiting example of a top view on a basic loop memory cell with a clad covering the optical loop. The input armlet 1302 is coupled into optical loop 1303 (the dashed line is for better understanding the configuration of the optical loop underneath the clad, all couplers can be used) that is covered by a clad 1304. The optical loop 1303 can couple into the output armlet 1305 depending if the refractive index is open 403 or closed 404 (that can be replaced with variable coupling controls 1212). The input clad side 1306 can be better understood referring to the non-limiting example of side view on the input clad facet, where 1308 is clad covering the side and 1309 is the input armlet 1302 cross section. The output clad side 1307 can be better understood referring to the non-limiting example of a side view on the output clad facet. Where 1308 is clad covering the side and 1310 is the optical loop 1303 coupling length 207 side view, the coupling length 207 is depended on distance 206, between the optical loop 1303 and the output armlet 1305, and the refractive indexes. Note any materials can be used as long as the refractive index difference between the waveguide and the surroundings creates less propagation loss.

Given the specific application for which the loop memory cell is to be used, including the wavelength(s) at which the loop memory cell is to operate, one skilled in the art will be able to select the type of: waveguide, loop shape, sizes and distances, direction of propagation, coupling methods, coupling fully or partially, the refractive index changer, the amount of input and output armlets and their direction, parallel or series connection between the loop memory cell, a loop memory cell within a loop memory cell, or by adding additional accessories or a clad.

Variety of optical complex processing blocks, algorithms and logic gats can be implemented with the loop memory cell, such as NOT, AND, OR, NAND, NOR, XOR and XNOR gates, and convolutional codes, Viterbi algorithm, SHA codes for blockchain mining algorithm (such as bitcoin) etc.

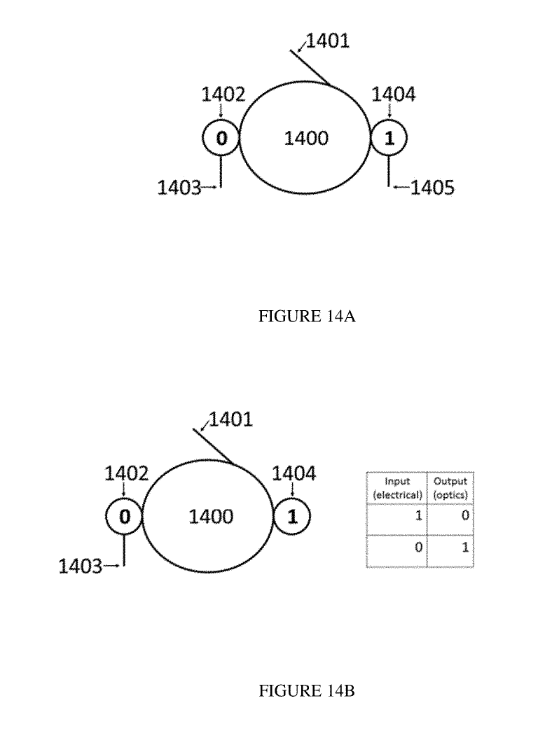

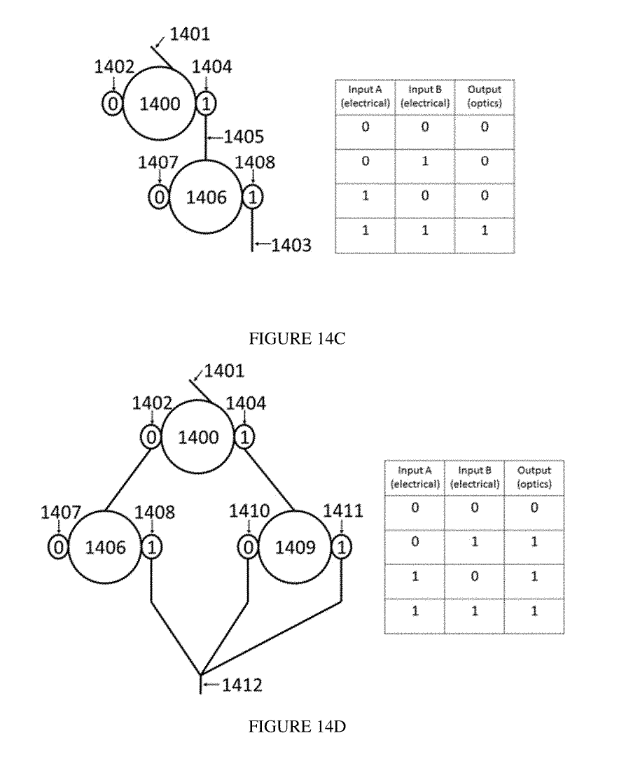

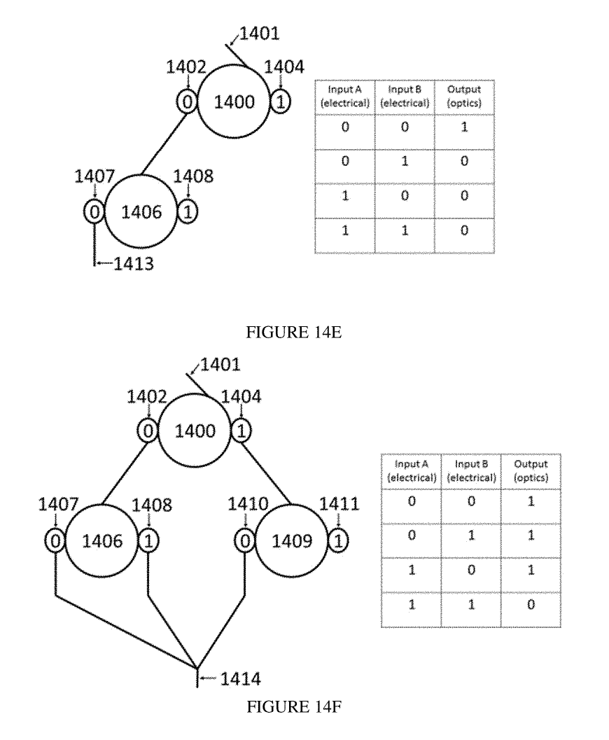

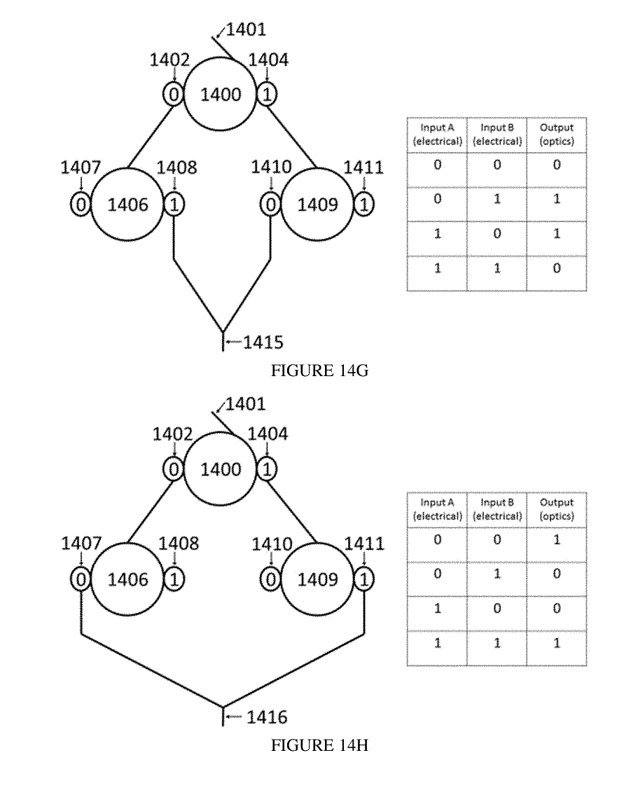

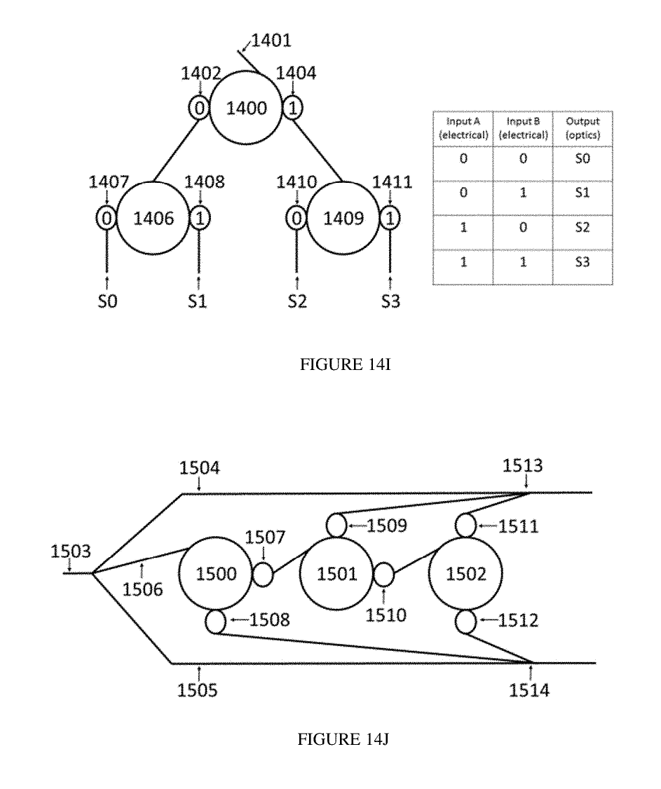

Referring to FIG. 14A, non-limiting example of a loop memory cell drawing with two exit armlets, this non-limiting example shows a basic concept of a loop memory cell with two armlets, where one of the exit armlets is an output for electrical bit zero (0) and the other exit armlet is for electrical bit of one (1). In this implementation, the two exit armlets (armlet zero 1042 and armlet one 1404) are constructed to activate coupling by different electrical signals, for example on/off (present/absence) of electrical signals. The input armlet 1401 is coupled into loop memory cell 1400 that contains the two exit armlets. Exit armlet zero 1402 directs the optical signal to output waveguide 1403 exit when the electrical signal is zero (deactivating the electrical signal that activates coupling between memory cell 1400 and the output waveguide 1403). Exit armlet one 1404 directs the optical signal to output waveguide 1405 exit when the electrical signal is one (an active electrical signal, referred to as “one”, activates coupling between memory cell 1400 and the output waveguide 1405).

As shown in the following figures, combinations of the basic structure of FIG. 14A (loop memory cells and varying activation of exit output couplers) can be used to construct basic and complex logic gates and processing functions.

Referring to FIG. 14B, non-limiting example of a NOT logic gate created by a loop memory cell, this non-limiting example shows a NOT gate created by a loop memory cell with two armlets, where only the zero exit armlet is connected. The input armlet 1401 is coupled into loop memory cell 1400 that contains exit armlet 1402 that directs the optical signal to 1403 exit when the electrical signal is zero. Exit armlet 1404 is closed and do not extract an optical signal (when the electrical signal is one). The table shows the electrical input and the optical output, which creates a NOT logic gate.

Referring to FIG. 14C, non-limiting example of an AND logic gate created by a loop memory cell, this non-limiting example shows an AND gate created by a combination of two loop memory cells, where each loop memory cell gets one electrical input. The input armlet 1401 is coupled into loop memory cell 1400 that contains a closed exit armlet 1402 (when the electrical signal is zero), loop memory cell 1400 is connected to electrical input A. Exit armlet 1404 directs the optical signal to 1405 exit when the electrical signal is one. 1405 is the input armlet of loop memory cell 1406 that contains a closed exit armlet 1407 (when the electrical signal is zero), loop memory cell 1406 is connected to electrical input B. Exit armlet 1408 directs the optical signal to 1403 exit, the optical output. The table shows the electrical input A on loop memory cell 1400, electrical input B on loop memory cell 1406 and the optical output, which creates an AND logic gate.

Referring to FIG. 14D, non-limiting example of an OR logic gate created by a loop memory cell, this non-limiting example shows an OR gate created by a combination of three loop memory cells. The input armlet 1401 is coupled into loop memory cell 1400 that is connected to electrical input A, and contains exit armlets 1402 and 1404 that directs the optical signal when the electrical signal is zero and one respectively. Exit armlet 1402 directs the optical signal to loop memory cell 1406 when the electrical signal A is zero, exit armlet 1404 directs the optical signal to loop memory cell 1409 when the electrical signal A is one. Loop memory cell 1406 contains a closed exit armlet 1407 when the electrical signal B is zero, exit armlet 1408 directs the optical signal when the electrical signal B is one, to 1412 exit, the optical output. Loop memory cell 1409 contains exit armlet 1410 directs the optical signal when the electrical signal B is zero and exit armlet 1411 directs the optical signal when the electrical signal B is one, to 1412 exit, the optical output. The table shows the electrical input A on loop memory cell 1400, electrical input B on loop memory cells 1406, 1409 and the optical output, which creates an OR logic gate.

Referring to FIG. 14E, non-limiting example of an NOR logic gate created by a loop memory cell, this non-limiting example shows an NOR gate created by a combination of two loop memory cells, where each loop memory cell gets one electrical input. The input armlet 1401 is coupled into loop memory cell 1400 is connected to electrical input A, and contains a closed exit armlet 1404 (when the electrical signal is one). Exit armlet 1402 directs the optical signal to loop memory cell 1406 when the electrical signal is zero. Loop memory cell 1406 is connected to electrical input B, and contains a closed exit armlet 1408 (when the electrical signal is one). Exit armlet 1407 directs the optical signal to 1413 exit, the optical output. The table shows the electrical input A on loop memory cell 1400, electrical input B on loop memory cell 1406 and the optical output, which creates an NOR logic gate.

Referring to FIG. 14F, non-limiting example of an NAND logic gate created by a loop memory cell, this non-limiting example shows an NAND gate created by a combination of three loop memory cells. The input armlet 1401 is coupled into loop memory cell 1400 that is connected to electrical input A, and contains exit armlets 1402 and 1404 that directs the optical signal when the electrical signal is zero and one respectively. Exit armlet 1402 directs the optical signal to loop memory cell 1406 when the electrical signal A is zero, exit armlet 1404 directs the optical signal to loop memory cell 1409 when the electrical signal A is one. Loop memory cell 1406 directs the optical signal to 1414 exit, the optical output, from exit armlet 1407 when the electrical signal B is zero and exit armlet 1408 when the electrical signal B is one. Loop memory cell 1409 contains a closed exit armlet 1411 (when the electrical signal B is one, and exit armlet 1410 directs the optical signal when the electrical signal B is zero to 1414 exit, the optical output. The table shows the electrical input A on loop memory cell 1400, electrical input B on loop memory cells 1406, 1409 and the optical output, which creates an NAND logic gate.

Referring to FIG. 14G, non-limiting example of an XOR logic gate created by a loop memory cell, this non-limiting example shows an XOR gate created by a combination of three loop memory cells. The input armlet 1401 is coupled into loop memory cell 1400 that is connected to electrical input A, and contains exit armlets 1402 and 1404 that directs the optical signal when the electrical signal is zero and one respectively. Exit armlet 1402 directs the optical signal to loop memory cell 1406 when the electrical signal A is zero, exit armlet 1404 directs the optical signal to loop memory cell 1409 when the electrical signal A is one. Loop memory cell 1406 contains a closed exit armlet 1407 when the electrical signal B is zero, and directs the optical signal to 1415 exit, the optical output, from exit armlet 1408 when the electrical signal B is one. Loop memory cell 1409 contains a closed exit armlet 1411 (when the electrical signal B is one, and exit armlet 1410 directs the optical signal when the electrical signal B is zero to 1415 exit, the optical output. The table shows the electrical input A on loop memory cell 1400, electrical input B on loop memory cells 1406, 1409 and the optical output, which creates an XOR logic gate.

Referring to FIG. 14H, non-limiting example of an XNOR logic gate created by a loop memory cell, this non-limiting example shows an XNOR gate created by a combination of three loop memory cells. The input armlet 1401 is coupled into loop memory cell 1400 that is connected to electrical input A, and contains exit armlets 1402 and 1404 that directs the optical signal when the electrical signal is zero and one respectively. Exit armlet 1402 directs the optical signal to loop memory cell 1406 when the electrical signal A is zero, exit armlet 1404 directs the optical signal to loop memory cell 1409 when the electrical signal A is one. Loop memory cell 1406 contains a closed exit armlet 1408 when the electrical signal B is one, and directs the optical signal to 1416 exit, the optical output, from exit armlet 1407 when the electrical signal B is zero. Loop memory cell 1409 contains a closed exit armlet 1410 when the electrical signal B is zero, and exit armlet 1411 directs the optical signal when the electrical signal B is one to 1416 exit, the optical output. The table shows the electrical input A on loop memory cell 1400, electrical input B on loop memory cells 1406, 1409 and the optical output, which creates an XNOR logic gate.

Referring to FIG. 14I, non-limiting example of a Trellis diagram created by a loop memory cell, this non-limiting example shows a Trellis diagram created by a combination of three loop memory cells. The Trellis diagram acts as a convolutional encoder and by finding the shortest path as Viterbi algorithm. The input armlet 1401 is coupled into loop memory cell 1400 that is connected to electrical input A, and contains exit armlets 1402 and 1404 that directs the optical signal when the electrical signal is zero and one respectively. Exit armlet 1402 directs the optical signal to loop memory cell 1406 when the electrical signal A is zero, exit armlet 1404 directs the optical signal to loop memory cell 1409 when the electrical signal A is one. Exit armlet 1407 directs the optical signal to the optical output exit S0 when the electrical signal B is zero, exit armlet 1408 directs the optical signal to the optical output exit S1 when the electrical signal B is one. Exit armlet 1410 directs the optical signal to the optical output exit S2 when the electrical signal B is zero, exit armlet 1411 directs the optical signal to the optical output exit S3 when the electrical signal B is one. The table shows the electrical input A on loop memory cell 1400, electrical input B on loop memory cells 1406, 1409 and the optical outputs, which create a Trellis diagram.

Referring to FIG. 14J, non-limiting example of a convolutional code created by a loop memory cell, this non-limiting example shows a three-memory cell convolutional code created by a combination of three loop memory cells and creating two outputs. The input 1503 is divided to three separated inputs, two reference inputs 1504 and 1505, and input 1506 the input armlet of loop memory cell 1500. The loop memory cell 1500 contains two exit armlets 1507 and 1508 that are open or closed depending on the electrical data in the cell. Exit armlet 1508 directs the optical signal to the combined optical output 1514, exit armlet 1507 directs the optical signal to the next loop memory cell 1501 that contains two exit armlets 1509 and 1510 that are open or closed depending on the electrical data in the cell. Exit armlet 1509 directs the optical signal to the combined optical output 1513. Exit armlet 1510 directs the optical signal to the next loop memory cell 1502 that contains two exit armlets 1511 and 1512 that are open or closed depending on the electrical data in the cell. Exit armlets 1511 and 1512 direct the optical signal to the combined optical outputs 1513 and 1514 respectively.

In general, the loop memory cell can be described as an electro optical memory cell or modulator that can store optical data in a loop and release it on demand, by changing the electric energy that changes the refractive index in the output armlet (the exit). Note, different ways to change the refractive index can be used, including but not limiting to electrical, optical or thermal energy change, making the loop memory cell an all optical memory cell or a thermo optical memory cell or modulator.

A preferred application is the configuration and use of the loop memory cell, which contains a minimum of one optical loop coupled in and out with a minimum of one input armlet and one output armlet, the input armlet can couple only in one direction and the output armlet can couple or not according to the refractive index changer. In other words, the loop memory cell is configured to collect the input data and store it in the loop until needed. Obviously, in a case where the data needs to stay stored in the loop and go to the output at the same time (depending on the application), the data can be partially coupled, as described before.

The shape of each loop memory cell and the orientation of the loop memory cell parts (optical loop(s), input armlet(s), output armlet(s) etc.) to each other are dependent on their specific application. Different complex processing blocks and algorithms can benefit from a loop memory cell having a different configuration of its parts. Although the above non-limiting example shows simple configurations of the loop memory cell, this should not be interpreted as limiting, and other shapes can be used for the loop(s), input and output armlet(s), coupling techniques, refractive index changer etc. Based on this description, one skilled in the art will be able to design a loop memory cell, including but not limited to selection of the lengths, angles, widths, shape, and orientation of the loop(s) and armlet(s), and all the required specifications, for a specific application.

The above examples are non-limiting, and other combinations are possible, for example, loop memory cell with multiple loops, inputs, and output. It is foreseen that additional research including selection, simulation, and testing of the various parameters for implementations of the current embodiment are possible. A key feature of the current embodiment is the use of optical loop(s) coupled with an input and output armlets, and the specific implementation of the loop memory cell will depend on the application to which the loop memory cell is used. Based on the above description, one skilled in the art will be able to select the quantity, length(s), shape, angle(s), and width(s) of the loop memory cell for a specific application.

A loop memory cell with different parameters such as different shape loops, different couplers, between one and three input and output armlets and different configurations has been shown to provide improved storage time and efficiency compared to conventional memory cells, and is a preferred implementation.

The choices used to assist in the description of this embodiment should not detract from the validity and utility of the invention. It is foreseen that more general choices including, but not limited to materials, number of loops and armlets, couplers and configuration can be used, depending on the application.

The use of simplified calculations to assist in the description of this embodiment should not detract from the utility and basic advantages of the invention.

It should be noted that the above-described examples, numbers used, and exemplary calculations are to assist in the description of this embodiment. Inadvertent typographical and mathematical errors should not detract from the utility and basic advantages of the invention.

It will be appreciated that the above descriptions are intended only to serve as examples, and that many other embodiments are possible within the scope of the present invention as defined in the appended claims.

What is claimed is:

1. An apparatus comprising:
(a) an optical loop with at least one one-way input coupler,
(b) at least one output coupler, and
(c) at least one output variable coupling control,
wherein said variable coupling control is configured for coupling said optical loop to a respective one of said output coupler.

2. The apparatus of claim 1 wherein one or more of said at least one one-way input coupler is coupled to a respective input optical signal and said optical loop receives said input optical signal via said one-way input coupler.

3. The apparatus of claim 2 wherein one or more of said respective input optical signals are coupled to respective one-way input coupler is an input variable coupling control.

4. The apparatus of claim 2 wherein said input optical signal is carried by an input waveguide.

5. The apparatus of claim 1 wherein said one-way input coupler is configured to allow an optical signal to be coupled only into said optical loop.

6. The apparatus of claim 1 wherein said variable coupling control is configured to change a refractive index between said optical loop and said output coupler so as to configure said variable coupling control as a refractive index changer.

7. The apparatus of claim 6 wherein said change is affected by an implementation selected from the group consisting of:
(a) Electrical refractive index change;
(b) Optical refractive index change;
(c) Thermo refractive index change;
(d) External materials refractive index change;
(e) Graphene refractive index change; and
(f) Graphene capacitor refractive index change.

8. The apparatus of claim 1 wherein said output coupler outputs an optical signal from said optical loop via said output variable control coupling.

9. The apparatus of claim 1 wherein said optical loop, said input coupler, and said output coupler construction is selected from the group consisting of:
(a) optical fibers;
(b) photonic integrated circuit (PIC) waveguides; and
(c) free space propagation.

10. The apparatus of claim 1 wherein said optical loop repeatedly cycles an electromagnetic signal along a waveguide path.

11. The apparatus of claim 1 wherein said output coupler is coupled to an output waveguide.

12. The apparatus of claim 11 further including at least one adjacent waveguide, wherein each of said adjacent waveguides is respectively coupled to another adjacent waveguide via a respective output variable coupling control.

13. The apparatus of claim 12 wherein each of said adjacent waveguides is coupled to at least one said one-way input coupler.

14. The apparatus of claim 1 wherein said at least one said output coupler is coupled to at least one said one-way input coupler.

15. The apparatus of claim 1 further including a second apparatus connected in parallel to the first apparatus via at least one said one-way input coupler.

16. The apparatus of claim 1 further including a second apparatus having a respective one-way input coupler, and including an input waveguide, said first apparatus and said second apparatus connected to said input waveguide via respective one-way input couplers.

17. The apparatus of claim 1 further including a second apparatus having a second one-way input coupler, wherein one said output coupler of the apparatus is connected in series to said second one-way input coupler.

18. The apparatus of claim 1 wherein said output variable coupling control is configured on a second optical loop, said second optical loop coupled to said optical loop.

19. The apparatus of claim 1 wherein said variable coupling control is controlled by an electrical signal, to couple said optical loop to said output coupler, thereby coupling out an optical signal from said optical loop, said optical signal corresponding to storage of a pre-defined data in said optical loop.

20. The apparatus of claim 19 further including:
(a) a second output coupler, and
(b) a second output variable coupling control controlled by a second electrical signal for coupling said optical loop to said second output coupler thereby coupling out said optical signal.
